(19) United States
(12) Patent Application Publication
(10) Pub. No.: US 2013/0101871 A1
(43) Pub. Date: Apr. 25, 2013

(54) PROTECTIVE CIRCUIT MODULE AND BATTERY PACK HAVING THE SAME

(71) Applicant: Bohyun Byun, Yongin-si (KR)

(72) Inventor: Bohyun Byun, Yongin-si (KR)

(21) Appl. No.: 13/554,811

(22) Filed: Jul. 20, 2012

Related U.S. Application Data
(60) Provisional application No. 61/549,445, filed on Oct. 20, 2011.

(51) Int. Cl. H05K 7/06; H01M 2/00

(52) U.S. Cl. 429/7; 361/783

(57) ABSTRACT

A protective circuit module includes a printed circuit board; and an electronic device on the printed circuit board, the electronic device including: an integrated circuit chip; at least one electrical component electrically coupled to the integrated circuit chip; and an encapsulating portion, the encapsulating portion encapsulating the integrated circuit chip and a portion of the at least one electrical component, wherein another portion of the at least one electrical component is outside the encapsulating portion.

### CROSS-REFERENCE TO RELATED APPLICATION

This application claims the benefit of and priority to U.S. Provisional Application No. 61/549,445, filed on Oct. 20, 2011, in the United States Patent and Trademark Office, the disclosure of which is incorporated herein in its entirety by reference.

### BACKGROUND

1. Field

Aspects of the present invention relate to a protective circuit module and a battery pack including the same.

2. Description of Related Art

In general, a lithium-based secondary battery such as a lithium ion secondary battery or a lithium polymer secondary battery has a higher energy density per unit weight and a smaller mass than a typical lead storage battery, a nickel/cadmium (Ni—Cd) battery, or a nickel/hydrogen (Ni—MH) battery. A lithium-based secondary battery may be used as a power source for various portable electronic devices such as smart phones, cellular phones, notebook computers, or electronic tools.

However, since the lithium-based secondary battery has an unstable chemical composition, it may be highly susceptible to damages in an event of an abnormal operation, such as a puncture, compression, external short, over-charge, over-discharge, over-current, heating, dropping, cutting, etc. Thus, in order to protect the secondary battery from over-charge, over-discharge, or over-current or to prevent the secondary battery from deteriorating in performance, a battery pack is typically manufactured by installing a protective circuit module on the secondary battery.

### SUMMARY

Aspects of the present invention provide a protective circuit module, which can simplify mounting of components and reduce component mounting costs, and may have a reduced overall size, and a battery pack having the same.

Aspects of the present invention also provide a protective circuit module, which has portions of electrical components (e.g., passive devices) positioned inside an encapsulating portion, thereby enhancing the strength of the electrical components (e.g., passive devices), and a battery pack including the same.

Aspects of the present invention further provide a protective circuit module, which has a portion of an electrical component (e.g., a passive device) positioned outside an encapsulating portion, thereby enabling easy determination of an operational failure, and a battery pack having the same.

At least one of the above and other features and aspects may be realized by providing a protective circuit module including: a printed circuit board; and an electronic device on the printed circuit board, the electronic device including: an integrated circuit chip; at least one electrical component electrically coupled to the integrated circuit chip; and an encapsulating portion, the encapsulating portion encapsulating the integrated circuit chip and a portion of the at least one electrical component, wherein another portion of the at least one electrical component is outside the encapsulating portion.

The at least one electrical component may include: a first terminal inside the encapsulating portion; a device unit electrically coupled to the first terminal; and a second terminal coupled to the device unit and outside the encapsulating portion.

A portion of the device unit may be inside the encapsulating portion, and another portion of the device unit may be outside the encapsulating portion.

The first and second terminals may be on the printed circuit board.

The first terminal may be coupled to the integrated circuit chip via a conductive wire.

The at least one electrical component may include a resistor.

The at least one electrical component may include a capacitor.

The integrated circuit chip may be on a chip mounting board.

The electronic device may further include a discharge control switch and a charge control switch on a switch mounting board.

Bottom surfaces of the first terminal and the chip mounting board may be exposed to the outside of the encapsulating portion, and a bottom surface of the switch mounting board may be entirely encapsulated in the encapsulating portion.

Bottom surfaces of the first terminal of the at least one electrical component, the encapsulating portion, and the chip mounting board may be coplanar with each other.

The protective circuit module may further include a plurality of wiring patterns on the printed circuit board, and at least one of the first terminal, the second terminal or the chip mounting board may be on a corresponding one of the plurality of wiring patterns.

At least one of the wiring patterns may be located between the encapsulating portion and the printed circuit board, and at least another one of the wiring patterns may not be located between the encapsulating portion and the printed circuit board.

According to another embodiment of the present invention, a battery pack includes: a battery cell including at least one electrode terminal; a protective circuit module (PCM) electrically coupled to the at least one electrode terminal of the battery cell, the PCM including a printed circuit board and an electronic device on the printed circuit board, wherein the electronic device includes an integrated circuit chip, at least one electrical component electrically coupled to the integrated circuit chip, and an encapsulating portion, the encapsulating portion encapsulating the integrated circuit chip and a portion of the at least one electrical component, wherein another portion of the at least one electrical component is outside the encapsulating portion; and at least one electrode pad on the PCM.

The electronic device may further include a discharge control switch and a charge control switch.

The PCM may be coupled to the at least one electrode terminal via a thermal safety device.

The at least one electrode pad may include a positive or negative electrode pad and the at least one electrode terminal may include a positive or negative electrode terminal.

The thermal safety device may include: a first lead plate coupled to the positive or negative electrode terminal; a thermal safety component coupled to the first lead plate; and a second lead plate coupled between the thermal safety component and the positive or negative electrode pad.

The at least one electrode pad may include a positive or negative electrode pad, and the PCM may be coupled to the battery cell via the electrode pad and a conductive connector.

The width of the PCM may be about one-half of the width of the battery cell.

In embodiments of the present invention, since a plurality of electrical components (e.g., a plurality of passive devices) are coupled to an encapsulating portion of an electronic device, they are mounted on a printed circuit board at the same time as the electronic device is mounted on the printed circuit board, thereby simplifying a mounting process and reducing mounting costs. In addition, when the plurality of electrical components (e.g., the plurality of passive devices) are coupled to the encapsulating portion of the electronic device, the overall size of the protective circuit module may be reduced.

In addition, in embodiments of the present invention, since portions of the electrical components (e.g., the passive devices) are coupled to the encapsulating portion of the electronic device, the strength of the electrical components (e.g., the passive devices) against an external impact can be enhanced.

Further, in embodiments of the present invention, since a portion (e.g., first and/or second terminals) of the electrical component (e.g., the passive device) is exposed to the outside of the electronic device, an electrical failure of the electrical component (e.g., the passive device), if any, can be easily determined.

### BRIEF DESCRIPTION OF THE DRAWINGS

FIG. 1 is a circuit diagram illustrating an exemplary protective circuit module according to an embodiment of the present invention.

FIGS. 2A and 2B are a plan view and a bottom view, respectively, of a protective circuit module according to an embodiment of the present invention, and FIG. 2C is a plan view of a printed circuit board before an electronic device is mounted thereon.

FIGS. 3A and 3B are a plan view and a bottom view, respectively, of an electronic device in a protective circuit module according to an embodiment of the present invention.

FIGS. 4A and 4B are cross-sectional views taken along lines 4a-4a and 4b-4b, respectively, of FIG. 3A.

FIGS. 5A, 5B and 5C are cross-sectional views taken along lines 5a-5a, 5b-5b and 5c-5c, respectively, of FIG. 2A.

FIG. 6 is an exploded view of an example of a battery pack having a protective circuit module according to an embodiment of the present invention.

FIG. 7 is an exploded view of another example of a battery pack having a protective circuit module according to another embodiment of the present invention.

### DETAILED DESCRIPTION

Example embodiments will now be described more fully hereinafter with reference to the accompanying drawings such that the example embodiments can easily be made and used by those skilled in the art.

Throughout the specification, it will be understood that when an element or layer is referred to as being “on” or “connected to” another element or layer, it can be directly on or connected to the other element or layer, or intervening elements or layers may be present.

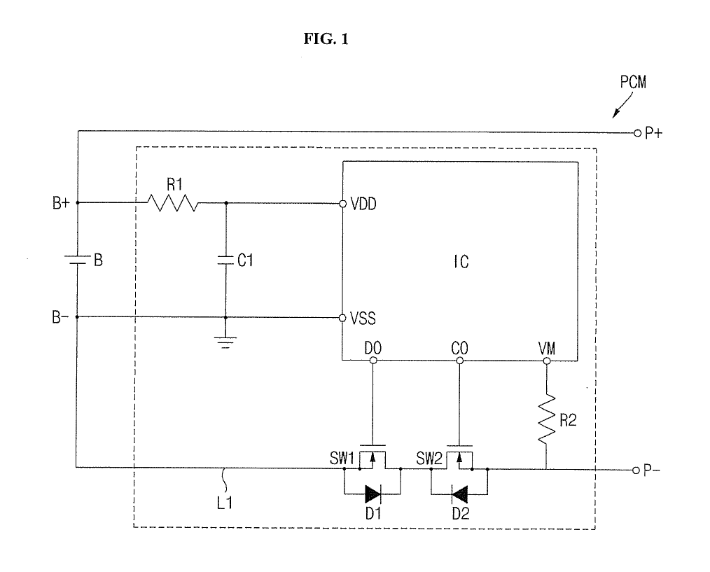

Referring to FIG. 1, a protective circuit module PCM includes an integrated circuit (IC) chip, a discharge control switch SW1, a charge control switch SW2, a first resistor R1, a second resistor R2 and a capacitor C1.

The IC chip is electrically connected to a secondary battery B to detect the voltage and current of the secondary battery B, and controls the discharge control switch SW1 or the charge control switch SW2 to prevent the secondary battery B from being over-discharged or over-charged. In addition, the IC chip controls the discharge control switch SW1 or the charge control switch SW2 to prevent over-current from flowing through the secondary battery B.

The discharge control switch SW1 is electrically connected between a charge/discharge line L1 and the IC chip and is turned off by a control signal of the IC chip when a voltage of the secondary battery B drops to a lower voltage level (e.g., a predetermined voltage level). Even when over-current flows from the secondary battery B during discharging, the discharge control switch SW1 is turned off. In addition, since a body diode D1 and the discharge control switch SW1 are connected in parallel, even if the discharge control switch SW1 is turned off, the secondary battery B can be charged.

The charge control switch SW2 is electrically connected between the charge/discharge line L1 and the IC chip and is turned off by the control signal of the IC chip when a voltage of the secondary battery B exceeds a higher voltage level (e.g., a predetermined voltage level). Even when over-current is supplied to the secondary battery B during charging, the charge control switch SW2 is turned off. In addition, since a body diode D2 and the charge control switch SW2 are connected in parallel, even if the charge control switch SW2 is turned off, the secondary battery B can be discharged.

The first resistor R1 is electrically connected between the secondary battery B and the IC chip, by which the IC chip can be protected from externally induced static electricity and the power supplied to the IC chip can be maintained at a substantially constant level.

The second resistor R2 is electrically connected between the charge/discharge line L1 and the IC chip, by which a value of current flowing in the charge/discharge line L1 can be sensed to allow the IC chip to properly control a protection operation. In an exemplary embodiment, when an electric short occurs between positive and negative electrode pack terminals P+ and P− of the protective circuit module PCM, the electric short is detected by the second resistor R2 to then be transmitted to the IC chip. Then, the IC chip turns off the discharge control switch SW1, thereby shutting down the flow of high current due to the external short.

The capacitor C1 is electrically connected between the first resistor R1 and the secondary battery B, by which a variation in the power supplied to the IC chip may be reduced or suppressed.

Reference symbols VDD, VSS, DO, CO, and VM denote a power supply terminal, a ground terminal, a gate connection terminal of the discharge control switch SW1, a gate connection terminal of the charge control switch SW2, and a connection terminal of the second resistor R2, respectively.

Meanwhile, the IC chip, the discharge control switch SW1, the charge control switch SW2, the first resistor R1, the second resistor R2 and the capacitor C1 may be defined as individual electronic devices. In addition, the first resistor R1, the second resistor R2 and the capacitor C1 may be defined as electrical components (or may also be referred to as passive devices). The electronic devices or electrical components may be mounted on the printed circuit board to then be electrically connected to each other.

In addition, as will later be described in detail, according to an embodiment the IC chip, the discharge control switch SW1, the charge control switch SW2, the first resistor R1, the second resistor R2 and the capacitor C1 are encapsulated by the encapsulating portion, and respective terminals of the first resistor R1, the second resistor R2 and the capacitor C1 are exposed or protruded to the outside of the encapsulating portion.

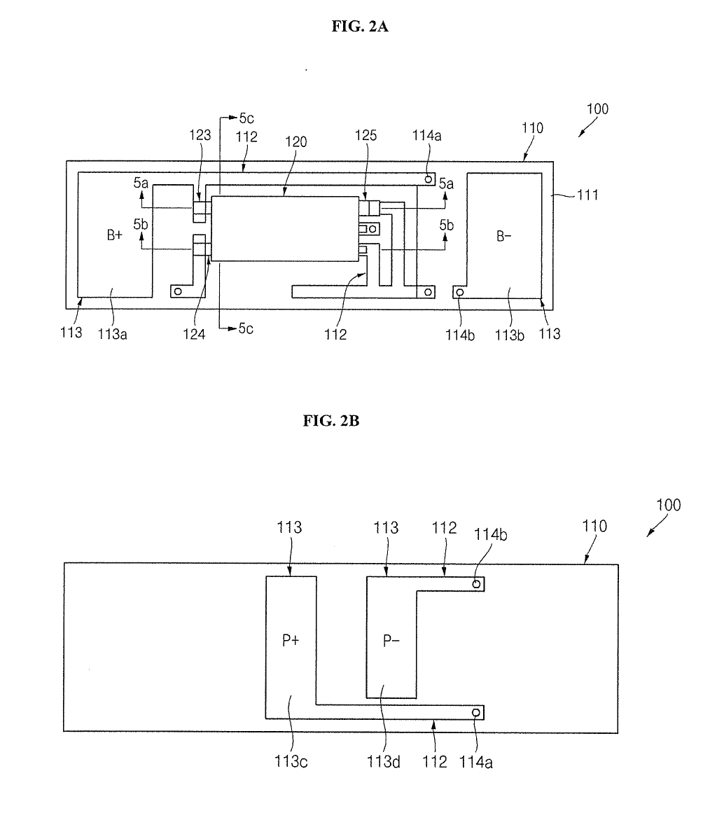

FIGS. 2A and 2B are a plan view and a bottom view, respectively, of a protective circuit module according to an embodiment of the present invention, and FIG. 2C is a plan view of a printed circuit board before an electronic device is mounted thereon.

As shown in FIGS. 2A to 2C, the protective circuit module 100 according to an embodiment of the present invention includes a printed circuit board 110 and an electronic device 120 mounted on the printed circuit board 110.

The printed circuit board 110 includes an insulating layer 111, and a plurality of wiring patterns 112 and a plurality of electrode pads 113 formed on the insulating layer 111.

The insulating layer 111 may be formed of a material selected from a phenol resin, an epoxy resin, polyimide and equivalents thereof, but aspects of the present invention are not limited thereto.

The wiring patterns 112 are formed on a surface of the insulating layer 111. In addition, the wiring patterns 112 may be formed of a material selected from copper and equivalents thereof, but aspects of the present invention are not limited thereto. The wiring patterns 112 may be used as charge/discharge paths through which high current mainly flows, or may be used to electrically connect respective terminals of the electronic device 120.

The electrode pads 113 include a battery positive electrode pad 113a and a battery negative electrode pad 113b, which are formed on one surface of the insulating layer 111, and a pack positive electrode pad 113c and a pack negative electrode pad 113d, which are formed on an opposite surface of the insulating layer 111. The electrode pads 113 are electrically connected to the wiring patterns 112. The positive electrode terminal B+ of the secondary battery B is electrically connected to the battery positive electrode pad 113a, and the negative electrode terminal B− of the secondary battery B is electrically connected to the battery negative electrode pad 113b. In addition, the pack positive electrode pad 113c and the pack negative electrode pad 113d are electrically connected to the wiring patterns 112 through conductive vias 114a and 114b passing through the insulating layer 111.

The electronic device 120 is electrically connected to the wiring patterns 112. As described above, in one embodiment the electronic device 120 includes an IC chip, a discharge control switch, a charge control switch and a plurality of electrical components (e.g., a plurality of passive devices). According to one embodiment, the electrical components (e.g., the passive devices) include a first resistor 123, a capacitor 124 and a second resistor 125.

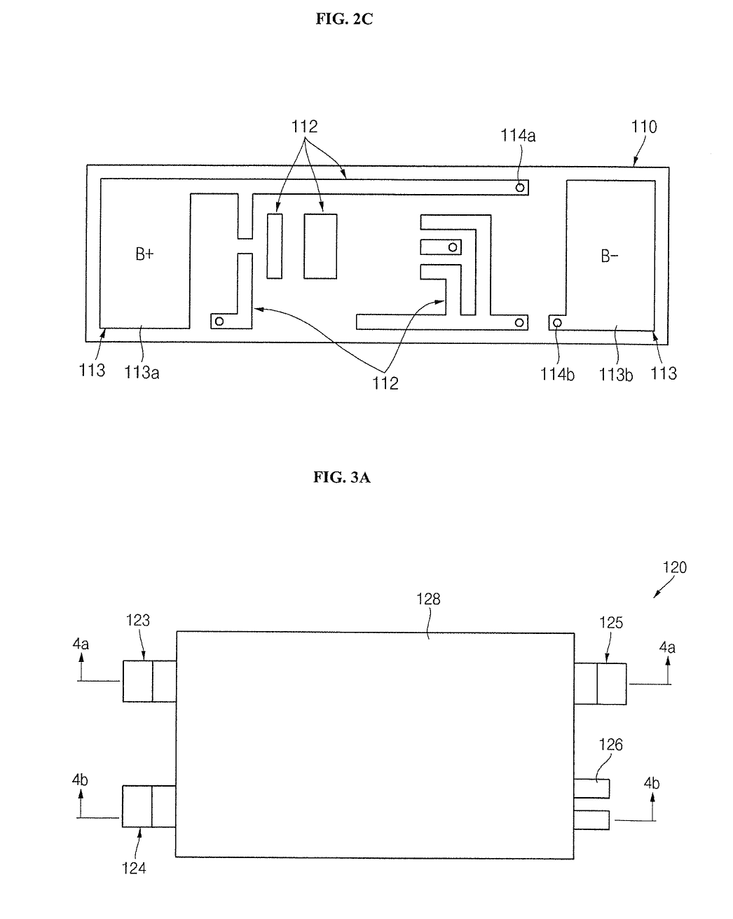

FIGS. 3A and 3B are a plan view and a bottom view, respectively, of an electronic device in a protective circuit module according to an embodiment of the present invention.

As shown in FIGS. 3A and 3B, the electronic device 120 may be wrapped with an encapsulating portion 128. The encapsulating portion 128 may be formed of a material selected from an epoxy molding compound (EMC) and equivalents thereof, but aspects of the present invention are not limited thereto.

The electrical components (e.g., the passive devices), including the first resistor 123, the capacitor 124 and the second resistor 125, are partially exposed or protruded to the outside of the encapsulating portion 128. In addition, a plurality of lead terminals 126 are also exposed or protruded to the outside of the encapsulating portion 128.

In one embodiment, the respective electrical components (e.g., the respective passive devices) include first terminals 123a, 124a and 125a, device units 123b, 124b and 125b, and second terminals 123c, 124c and 125c. Portions of the first terminals 123a, 124a and 125a and portions of the device units 123b, 124b and 125b are positioned inside the encapsulating portion 128, and the second terminals 123c, 124c and 125c and other portions of the device units 123b, 124b and 125b are protruded and extended to the outside of the encapsulating portion 128. In addition, since bottom surfaces of the first terminals 123a, 124a and 125a and the device units 123b, 124b and 125b are coplanar with a bottom surface of the encapsulating portion 128, the bottom surfaces of the first terminals 123a, 124a and 125a and the device units 123b, 124b and 125b are exposed to the outside. Moreover, since a bottom surface of a chip mounting board 121a having an IC chip 121 mounted thereon is coplanar with the bottom surface of the encapsulating portion 128, the bottom surface of the chip mounting board 121a is also exposed to the outside of the encapsulating portion 128.

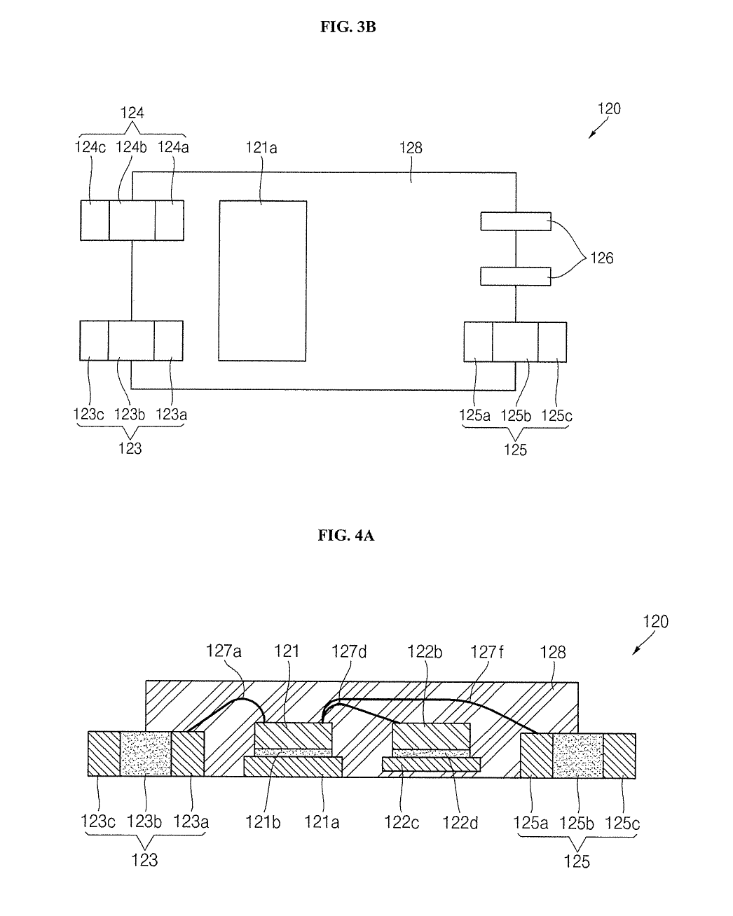

FIGS. 4A and 4B are cross-sectional views taken along lines 4a-4a and 4b-4b, respectively, of FIG. 3A.

As shown in FIGS. 4A and 4B, in one embodiment the electronic device 120 includes the IC chip 121, the chip mounting board 121a on which the IC chip 121 is mounted, a discharge control switch 122a, a charge control switch 122b, a switch mounting board 122c on which the discharge and charge control switches 122a and 122b are mounted, a first resistor 123 and a capacitor 124 positioned at one side of the integrated circuit chip 121, a second resistor 125 positioned at one side of the charge control switch 122b, lead terminals 126 positioned at one side of the discharge control switch 122a, a plurality of conductive wires 127a, 127b, 127c, 127d, 127e and 127f, and an encapsulating portion 128 that encapsulates the above-stated components.

Here, the conductive wire 127a electrically connects the integrated circuit chip 121 to the first resistor 123, the conductive wire 127b electrically connects the integrated circuit chip 121 to the capacitor 124, the conductive wire 127c electrically connects the integrated circuit chip 121 to the discharge control switch 122a, the conductive wire 127d electrically connects the integrated circuit chip 121 to the charge control switch 122b, the conductive wire 127e electrically connects the discharge control switch 122a to the lead terminal 126, and the conductive wire 127f electrically connects the integrated circuit chip 121 to the second resistor 125.

The electrical components (e.g., the passive devices) including the first resistor 123, the capacitor 124 and the second resistor 125, will now be described in more detail.

According to an embodiment, the first resistor 123 includes the first terminal 123a, the device unit 123b and the second terminal 123c. The first terminal 123a and a portion of the device unit 123b are positioned inside the encapsulating portion 128, and the other portion of the device unit 123b and the second terminal 123c are exposed and protruded to the outside of the encapsulating portion 128. Here, the bottom surfaces of the first terminal 123a, the device unit 123b and the second terminal 123c are coplanar with the bottom surface of the encapsulating portion 128. Therefore, the bottom surfaces of the first terminal 123a and the device unit 123b are exposed to the outside of the encapsulating portion 128 through the bottom surface of the encapsulating portion 128. In addition, the first terminal 123a of the first resistor 123 is electrically connected to the IC chip 121 through the conductive wire 127a.

Meanwhile, the capacitor 124 also includes a first terminal 124a, a device unit 124b and a second terminal 124c. The first terminal 124a and a portion of the device unit 124b are positioned inside the encapsulating portion 128, and the other portion of the device unit 124b and the second terminal 124c are protruded and extended to the outside of the encapsulating portion 128. Here, bottom surfaces of the first terminal 124a, the device unit 124b and the second terminal 124c are coplanar with the bottom surface of the encapsulating portion 128. Therefore, the bottom surfaces of the first terminal 124a and the device unit 124b are exposed to the outside of the encapsulating portion 128 through the bottom surface of the encapsulating portion 128. In addition, the first terminal 124a of the capacitor 124 is electrically connected to the IC chip 121 through the conductive wire 127b.

The second resistor 125 also includes a first terminal 125a, a device unit 125b and a second terminal 125c. The first terminal 125a and a portion of the device unit 125b are positioned inside the encapsulating portion 128, and the other portion of the device unit 125b and the second terminal 125c are protruded and extended to the outside of the encapsulating portion 128. Here, bottom surfaces of the first terminal 125a, the device unit 125b and the second terminal 125c are coplanar with the bottom surface of the encapsulating portion 128. Therefore, the bottom surfaces of the first terminal 125a and the device unit 125b are exposed to the outside of the encapsulating portion 128 through the bottom surface of the encapsulating portion 128. In addition, the first terminal 125a of the second resistor 125 is electrically connected to the IC chip 121 through the conductive wire 127f.

Meanwhile, a bottom surface of the chip mounting board 121a having the integrated circuit chip 121 mounted thereon is also coplanar with the bottom surface of the encapsulating portion 128. Therefore, the bottom surface of the chip mounting board 121a is exposed to the outside of the encapsulating portion 128 through the bottom surface of the encapsulating portion 128. Even if the chip mounting board 121a is mounted on wiring patterns 112 provided on the printed circuit board 110, since the IC chip 121 is mounted on the chip mounting board 121a using an insulating adhesive 121b, unwanted electrical shorts between the IC chip 121 and the wiring patterns 112 can be reduced or avoided.

However, the switch mounting board 122c on which the discharge control switch 122a and the charge control switch 122b are mounted is positioned inside the encapsulating portion 128 and is not exposed to the outside. Even if the switch mounting board 122c were exposed to the outside of the encapsulating portion 128, since the discharge control switch 122a and the charge control switch 122b are mounted on the switch mounting board 122c using a conductive adhesive 122d, unwanted electrical shorts could be reduced or avoided.

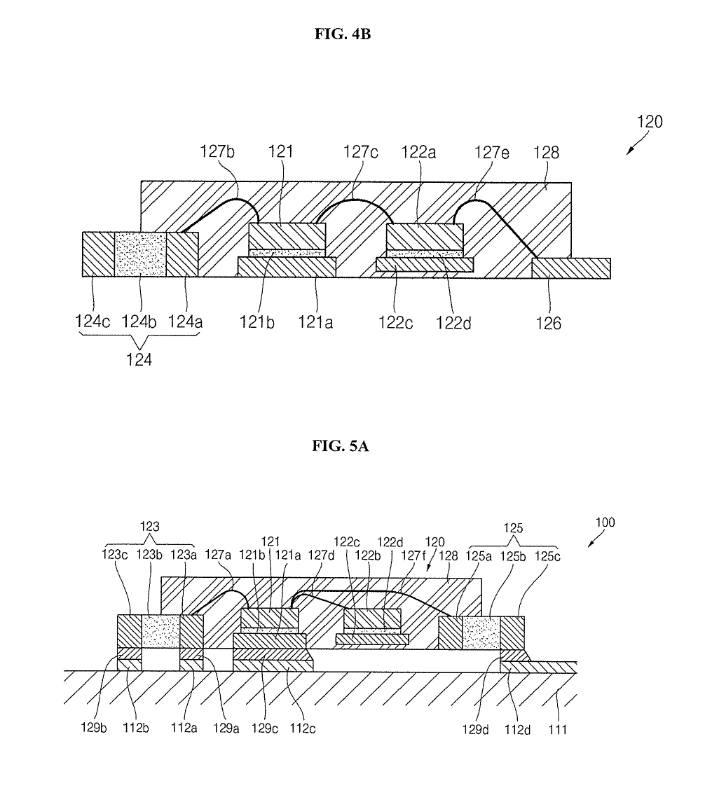

FIGS. 5A, 5B and 5C are cross-sectional views taken along lines 5a-5a, 5b-5b and 5c-5c, respectively, of FIG. 2A.

First, as shown in FIG. 5A, the first terminal 123a of the first resistor 123 positioned inside the encapsulating portion 128 is mounted on the wiring pattern 112a of the printed circuit board 110, which is provided under the encapsulating portion 128. In one embodiment, the first terminal 123a is mounted on the wiring pattern 112a via a solder 129a. In addition, the second terminal 123c of the first resistor 123 is protruded to the outside of the encapsulating portion 128 and is mounted on the wiring pattern 112b of the printed circuit board 110. Further, the chip mounting board 121a provided under the encapsulating portion 128 is mounted on the wiring pattern 112c of the printed circuit board 110 via a solder 129c. The second terminal 125c of the second resistor 125 is protruded to the outside of the encapsulating portion 128 and is mounted on the wiring pattern 112d of the printed circuit board 110 via a solder 129d. Here, the first terminal 125a of the second resistor 125 is connected to the IC chip 121 through the conductive wire 127f. However, it is not necessary for the first terminal 125a to be mounted on any wiring pattern of the printed circuit board 110.

As shown in FIG. 5B, the first terminal 124a of the capacitor 124 is positioned inside the encapsulating portion 128 and is mounted on the wiring pattern 112a of the printed circuit board 110 provided under the encapsulating portion 128. In one embodiment, the first terminal 124a is mounted on the wiring pattern 112a via a solder 129e. Here, the first terminal 124a of the capacitor 124 and the first terminal 123a of the first resistor 123 are electrically connected to each other through the wiring pattern 112a. Further, the lead terminal 126 is mounted on the wiring pattern 112f of the printed circuit board 110 via a solder 129g.

As shown in FIG. 5C, the first terminal 123a of the first resistor 123 and the first terminal 124a of the capacitor 124 are positioned inside the encapsulating portion 128 and are mounted on the wiring pattern 112a of the printed circuit board 110 through solders 129a and 129e, respectively. Therefore, the first resistor 123 and the capacitor 124 are electrically connected to each other, as shown in FIG. 1.

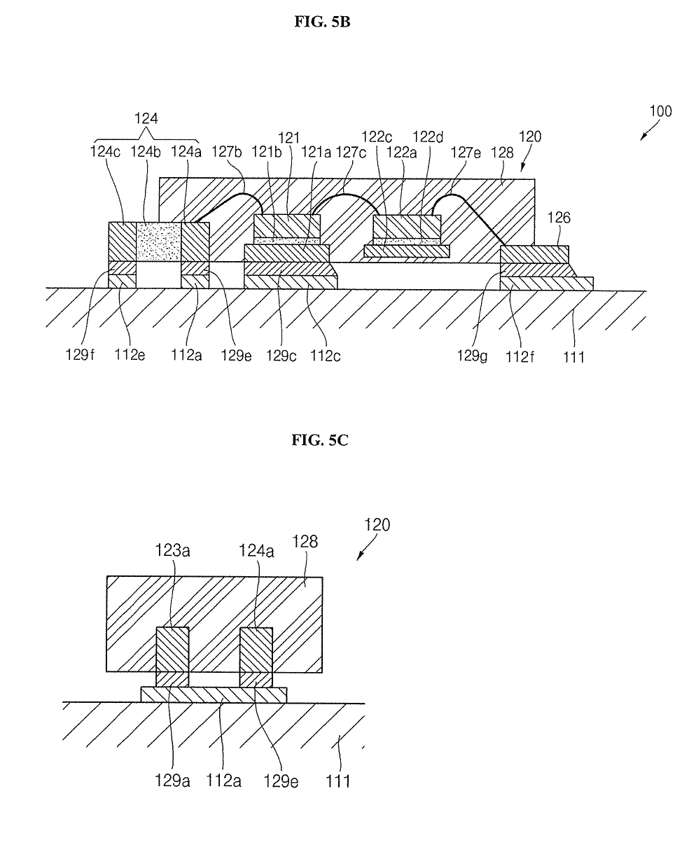

FIG. 6 is an exploded view of an example of a battery pack having a protective circuit module according to an embodiment of the present invention.

As shown in FIG. 6, the protective circuit module 100 may be electrically connected to a prismatic battery cell 210, thereby implementing a prismatic battery pack 200. In one embodiment, the protective circuit module 100 includes electrical components (e.g., passive devices) provided in one electronic device 120, including an IC chip, a discharge control switch, a charge control switch, a first resistor, a second resistor, and a capacitor, so that the protective circuit module 100 can be implemented with a considerably smaller size than the conventional protective circuit module. In an exemplary embodiment, the protective circuit module 100 can be manufactured to have a width of half to two thirds that of the prismatic battery cell 210.

In addition, in the prismatic battery cell 210, since a case 211 itself has, for example, a positive polarity, the case 211 and the battery positive electrode pad 113a of the protective circuit module 100 may be connected to each other with a conductive connector 213 interposed therebetween. Further, a negative electrode terminal 212 of the prismatic battery cell 210 and a battery negative electrode pad 113b of the protective circuit module 100 may be connected to each other through a thermal safety device interposed therebetween. In one embodiment, the thermal safety device is a PTC assembly 214 that includes a first lead plate 214a connected to the negative electrode terminal 212, a thermal safety component such as a PTC device 214b connected to the first lead plate 214a, and a second lead plate 214c connected to the PTC device 214b and the battery negative electrode pad 113b.

A resin may be interposed between the protective circuit module 100 and the prismatic battery cell 210, and the resin may wrap regions of the protective circuit module 100 other than a pack positive electrode pad 113c and a pack negative electrode pad 113d.

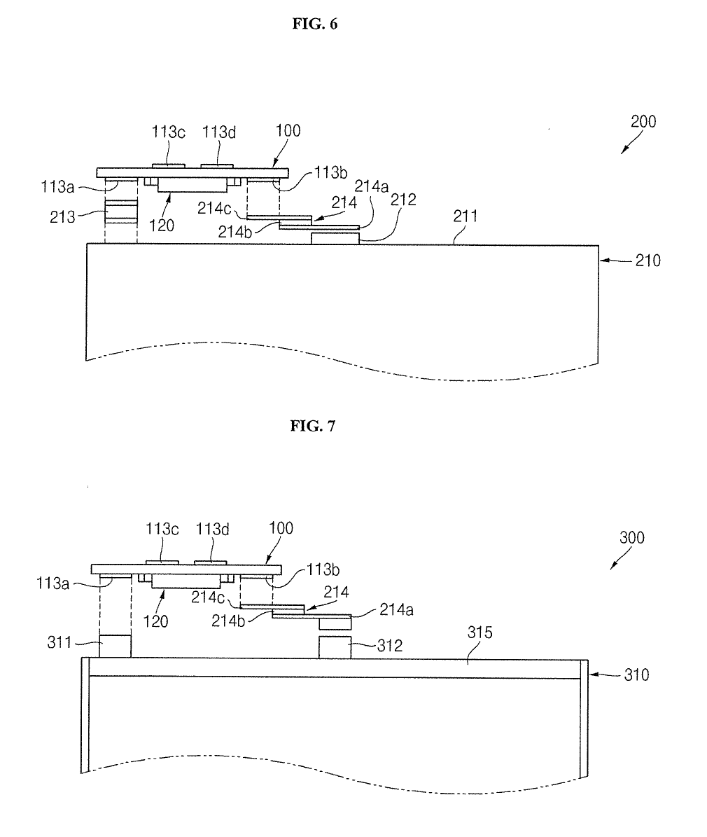

FIG. 7 is an exploded view of another example of a battery pack having a protective circuit module according to another embodiment of the present invention.

As shown in FIG. 7, the protective circuit module 100 may be electrically connected to a pouch-type battery cell 310, thereby implementing a pouch-type battery pack 300. As described above, the protective circuit module 100 can be manufactured to have a width of half to two thirds that of the pouch-type battery cell 310.

In addition, a positive electrode cell tab 311 of the pouch-type battery cell 310 and a battery positive electrode pad 113a of the protective circuit module 100 may be connected to each other. Further, a negative electrode cell tab 312 of the pouch-type battery cell 310 and a battery negative electrode pad 113b of the protective circuit module 100 may be connected to each other through a thermal safety device interposed therebetween. In one embodiment, the thermal safety device is a PTC assembly 214 that includes a first lead plate 214a connected to the negative electrode cell tab 312, a thermal safety component such as a PTC device 214b connected to the first lead plate 214a, and a second lead plate 214c connected to the PTC device 214b and the battery negative electrode pad 113b.

Alternatively, the positive electrode cell tab 311 and the negative electrode cell tab 312 may be bent, and the protective circuit module 100 may be seated on a terrace portion 315 provided in the pouch-type battery cell 310.

Exemplary embodiments of a protective circuit module and a battery pack having the same have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims and their equivalents.

DESCRIPTION OF SOME OF THE REFERENCE
NUMBERS IN THE DRAWINGS

| | |
|---|---|
| 100: Protective circuit module | |
| 110: Printed circuit board | 111: Insulating layer |
| 112a, 112b, 112c, 112d, 112e, | |
| 112f: Wiring pattern | |
| 113a, 113b: Battery positive electrode | |
| pad, Battery negative electrode pad | |
| 113c, 113d: Pack positive electrode pad, | |
| Pack negative electrode pad | |
| 114a, 114b: Conductive via | |
| 120: Electronic device | 121: Integrated circuit chip |
| 121a: Chip mounting board | 122a: Discharge control switch |
| 122b: Charge control switch | 122c: Switch mounting board |
| 123: First resistor | 124: Capacitor |
| 125: Second resistor | 126: Lead terminal |
| 127a, 127b, 127c, 127d, 127e, 127f: | |
| Conductive wire | |
| 128: Encapsulating portion | |
| 129a, 129b, 129c, 129d, 129e, 129f, | |
| 129g: Solder | |
| 200, 300: Battery pack | |
| 210: Prismatic battery cell | 211: Case |
| 212: negative electrode terminal | 213: Conductive connector |
| 214: PTC assembly | 214a: First lead plate |
| 214b: PTC device | 214c: Second lead plate |
| 310: Pouch-type battery cell | 311: Positive electrode cell tab |
| 312: negative electrode cell tab | 315: Terrace portion |

What is claimed is:

1. A protective circuit module comprising:
a printed circuit board; and
an electronic device on the printed circuit board, the electronic device comprising:
an integrated circuit chip;
at least one electrical component electrically coupled to the integrated circuit chip; and
an encapsulating portion, the encapsulating portion encapsulating the integrated circuit chip and a portion of the at least one electrical component, wherein another portion of the at least one electrical component is outside the encapsulating portion.

2. The protective circuit module of claim 1, wherein the at least one electrical component comprises:
a first terminal inside the encapsulating portion;
a device unit electrically coupled to the first terminal; and
a second terminal coupled to the device unit and outside the encapsulating portion.

3. The protective circuit module of claim 2, wherein a portion of the device unit is inside the encapsulating portion, and another portion of the device unit is outside the encapsulating portion.

4. The protective circuit module of claim 2, wherein the first and second terminals are on the printed circuit board.

5. The protective circuit module of claim 2, wherein the first terminal is coupled to the integrated circuit chip via a conductive wire.

6. The protective circuit module of claim 2, wherein the at least one electrical component comprises a resistor.

7. The protective circuit module of claim 2, wherein the at least one electrical component comprises a capacitor.

8. The protective circuit module of claim 2, wherein the integrated circuit chip is on a chip mounting board.

9. The protective circuit module of claim 8, wherein the electronic device further comprises a discharge control switch and a charge control switch on a switch mounting board.

10. The protective circuit module of claim 9, wherein bottom surfaces of the first terminal and the chip mounting board are exposed to the outside of the encapsulating portion, and wherein a bottom surface of the switch mounting board is entirely encapsulated in the encapsulating portion.

11. The protective circuit module of claim 8, wherein bottom surfaces of the first terminal of the at least one electrical component, the encapsulating portion, and the chip mounting board are coplanar with each other.

12. The protective circuit module of claim 8, further comprising a plurality of wiring patterns on the printed circuit board, wherein at least one of the first terminal, the second terminal or the chip mounting board is on a corresponding one of the plurality of wiring patterns.

13. The protective circuit module of claim 12, wherein at least one of the wiring patterns is located between the encapsulating portion and the printed circuit board, and at least another one of the wiring patterns is not located between the encapsulating portion and the printed circuit board.

14. A battery pack comprising:
a battery cell comprising at least one electrode terminal;
a protective circuit module (PCM) electrically coupled to the at least one electrode terminal of the battery cell, the PCM comprising a printed circuit board and an electronic device on the printed circuit board,
wherein the electronic device comprises an integrated circuit chip, at least one electrical component electrically coupled to the integrated circuit chip, and an encapsulating portion, the encapsulating portion encapsulating the integrated circuit chip and a portion of the at least one electrical component, wherein another portion of the at least one electrical component is outside the encapsulating portion; and
at least one electrode pad on the PCM.

15. The battery pack of claim 14, wherein the electronic device further comprises a discharge control switch and a charge control switch.

16. The battery pack of claim 14, wherein the PCM is coupled to the at least one electrode terminal via a thermal safety device.

17. The battery pack of claim 16, wherein the at least one electrode pad comprises a positive or negative electrode pad and the at least one electrode terminal comprises a positive or negative electrode terminal.

18. The battery pack of claim 17, wherein the thermal safety device comprises:
a first lead plate coupled to the positive or negative electrode terminal;
a thermal safety component coupled to the first lead plate; and
a second lead plate coupled between the thermal safety component and the positive or negative electrode pad.

19. The battery pack of claim 16, wherein the at least one electrode pad comprises a positive or negative electrode pad, the PCM being coupled to the battery cell via the electrode pad and a conductive connector.

20. The battery pack of claim 14, wherein the width of the PCM is about one-half of the width of the battery cell.
